(19) United States
(12) Patent Application Publication
(10) Pub. No.: US 2014/0333369 A1
(43) Pub. Date: Nov. 13, 2014

(54) KEY MODULE AND SIGNAL GENERATING METHOD THEREOF

(71) Applicant: Chih-Hsuan Lo, Hsinchu City (TW)

(72) Inventor: Chih-Hsuan Lo, Hsinchu City (TW)

(73) Assignee: ITE Tech. Inc., Hsinchu (TW)

(21) Appl. No.: 14/176,153

(22) Filed: Feb. 10, 2014

(30) Foreign Application Priority Data
May 8, 2013 (TW) 102116352

(51) Int. Cl. H03K 17/96

(52) U.S. Cl. CPC H03K 17/962
USPC 327/517

(57) ABSTRACT

A key module and a signal generating method of the key module are provided. The key module is suitable for an electronic device, the electronic device has a processing system, and the key module includes a detecting module and a controller. The detecting module includes a main electrode conductor and an assisting electrode conductor, where the assisting electrode conductor is disposed around the main electrode conductor. The controller is coupled to the main electrode conductor and the assisting electrode conductor. When the controller determines that a touch is detected by the main electrode conductor, but not detected by the assisting electrode conductor, the controller transmits a key signal to the processing system.

### CROSS-REFERENCE TO RELATED APPLICATION

This application claims the priority benefit of Taiwan application serial no. 102116352, filed on May 8, 2013. The entirety of the above-mentioned patent application is hereby incorporated by reference herein and made a part of this specification.

### BACKGROUND OF THE INVENTION

1. Field of the Invention

The present invention relates to a touch technology and in particular, to a key module and signal generating of the key module.

2. Description of Related Art

In General, an electronic device generally has a mechanical key. However, if the mechanical key is disposed on the electronic device, it may cause problems, such as a structure of the electronic device incapable of being light and compact, the electronic device body incapable of staying integrally formed. In addition, comparing with a capacitive key, lifespan of the mechanical key is commonly shorter than the capacitive key. Therefore, the capacitive key has replaced the mechanical key and become the mainstream of the electronic device.

However, for the electronic device having the capacitive key, the electronic device may correspondingly generate a sensing signal merely if a user quickly swipes the capacitive key using a finger. Thus, when the user does not actually want to press the capacitive key, but for example, just swipes the touch screen of the electronic device by the finger, the capacitive key may be accidentally touched, which would cause malfunction easily. Moreover, a conventional capacitive key scheme would be incapable of processing in case the user only puts the finger on the key region but not actually wants to press the key.

### SUMMARY OF THE INVENTION

Accordingly, the present invention is directed to a key module and a signal generating method of the key module that are capable of effectively preventing an electronic device from malfunction due to an accident touch of a user.

The present invention provides a key module suitable for an electronic device with a processing system. The key module includes a detecting module and a controller. The detecting module includes a main electrode conductor and at least one assisting electrode conductor. The assisting electrode conductor is disposed around the main electrode conductor. The controller is coupled to the main electrode conductor and the assisting electrode conductor. When the controller determines that a touch is detected by the main electrode conductor, but not detected by the assisting electrode conductor, the controller transmits a key signal to the processing system.

Furthermore, the present invention provides a signal generating method of a key module suitable for an electronic device with a processing system. The signal generating method of the key module comprises: providing a detecting module including a main electrode conductor and at least one assisting electrode conductor, wherein the assisting electrode conductor is disposed around the main electrode conductor; determining whether a touch is detected by the main electrode conductor, but not detected by the assisting electrode conductor; transmitting a key signal to the processing system when the touch is detected by the main electrode conductor, but not detected by the assisting electrode conductor.

To sum up, the present invention provides a key module and a signal generating method of the key module. The key signal is generated only when a touch is detected by the main electrode conductor in the key module touch but not detected by the assisting electrode conductor. Accordingly, the electronic device is effectively prevented from malfunction due to an accident touch of the user.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of an electronic device according to an embodiment of the present invention.

FIG. 2 is a schematic diagram of the detecting module according to a first embodiment of the present invention.

FIG. 3 is a schematic diagram of the detecting module according to a second embodiment of the present invention.

FIG. 4 is a schematic diagram of the detecting module according to a third embodiment of the present invention.

FIG. 5 is a schematic diagram of the detecting module according to a fourth embodiment of the present invention.

FIG. 6 is a schematic diagram of the detecting module according to a fifth embodiment of the present invention.

FIG. 7 is a schematic diagram of the detecting module according to a sixth embodiment of the present invention.

FIG. 8 is a flowchart of a signal generating method of a key module according to an embodiment of the present invention.

### DESCRIPTION OF THE EMBODIMENTS

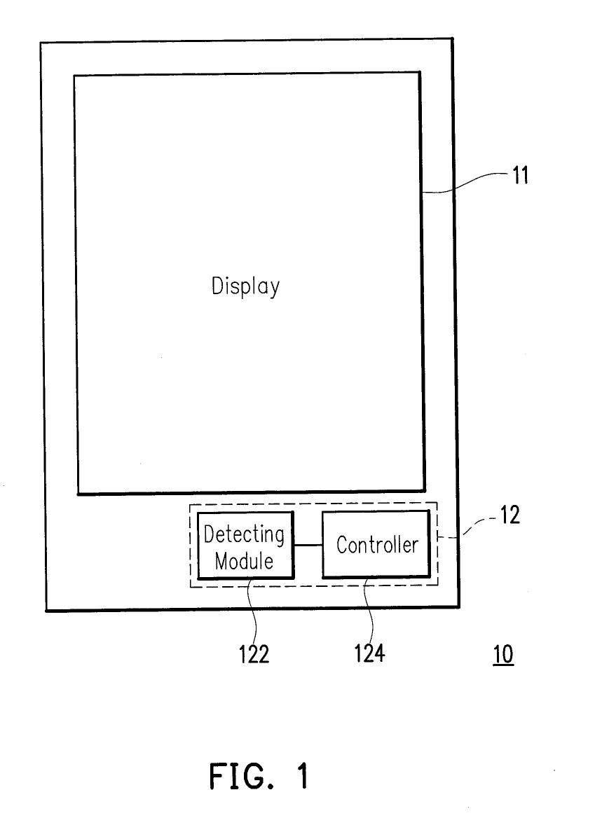

FIG. 1 is a schematic diagram of an electronic device according to an embodiment of the present invention. Referring to FIG. 1, the electronic device is, for example, a smart phone, a table PC, a game console, a personal digital assistant (PDA), a notebook, or desktop computer or any type of electronic device. The electronic device 10 may have a processing system. In the present embodiment, the processing system at least includes a processor and a memory, and the processor may operate an operation system (OS).

The electronic device 10 includes a display 11 and a key module 12. The display 11 is, for example, any type of display or touch display. For example, the display 11 may be a capacitive, resistive, or optical touch display, etc. In particular, the electronic device 10 is only an application of the key module 12 provided by the present invention, which constructs no limitations to the invention. For example, in one embodiment, the key module 12 may also be disposed on any type of electronic device without being equipped with a display, such as a touch pad or a touch table, which depends on actual requirements.

The key module 12 includes a detecting module 122 and a controller 124. The detecting module 122 serves to detect a touch of a user. For example, the detecting module 122 may be disposed on a specific position on the electronic device 10 and detects a touch operation of the user on the specific position or a position close to the specific position by using an input means (e.g., a finger or a stylus). The controller 124 is coupled to the detecting module 122 and serves to transform the touch detected by the detecting module 122 to a key signal according to a predetermined condition and transmit the key signal to the processing system of the electronic device 10. Several embodiments are described below as examples showing that the disclosure can actually be realized.

### First Embodiment

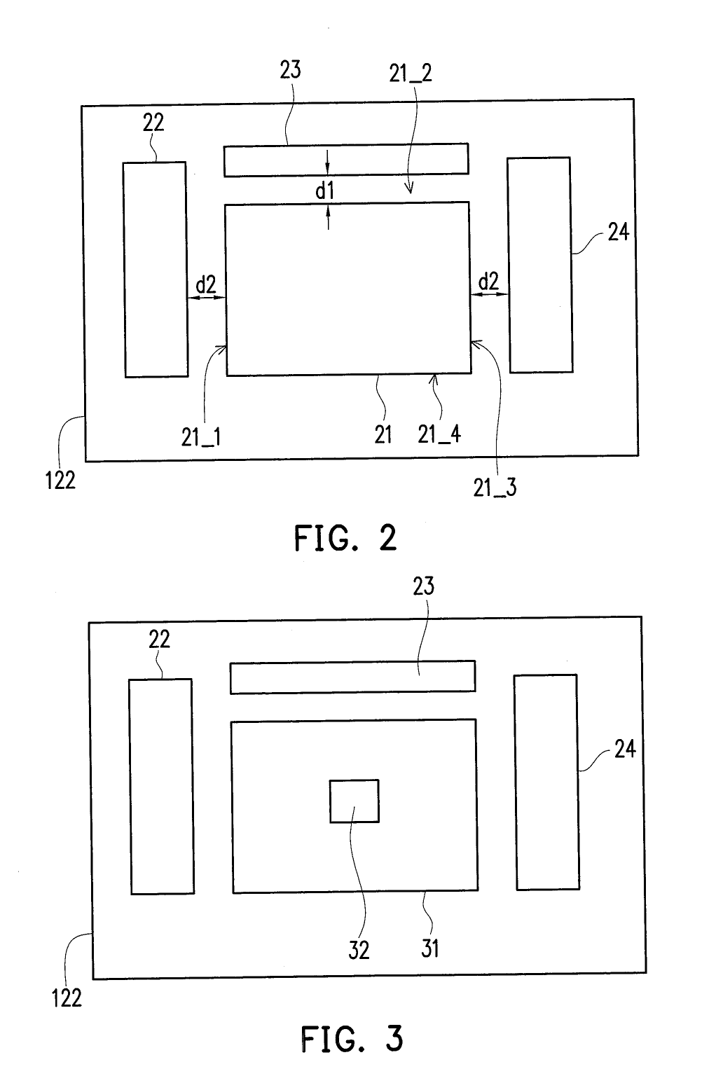

FIG. 2 is a schematic diagram of the detecting module 122 according to a first embodiment of the present invention. Referring to FIG. 2, the detecting module 122 includes a main electrode conductor 21, an assisting electrode conductor 22, an assisting electrode conductor 23, and an assisting electrode conductor 24. The assisting electrode conductor 22, the assisting electrode conductor 23, and the assisting electrode conductor 24 are disposed around the main electrode conductor 21.

Specifically, if it is defined that the main electrode conductor 21 has a side 21_1, a side 21_2, a side 213, and a side 214, the assisting electrode conductor 22 is disposed adjacent to the side 21_1 of the main electrode conductor 21, the assisting electrode conductor 23 is disposed adjacent to the side 21_2 of the main electrode conductor 21, the assisting electrode conductor 24 is disposed adjacent to the side 21_3 of the main electrode conductor 21, and the assisting electrode conductor 22 is disposed opposite to the assisting electrode conductor 24.

Furthermore, in order to explicitly clarify the directionality in FIG. 2, referring to FIG. 1 and FIG. 2, the assisting electrode conductor 23 may be substantially disposed between the display 11 and the main electrode conductor 21 so as to determine whether the user mistakenly touches the main electrode conductor 21 when operating the display 11. Moreover, it is assumed that a distance d1 is between the assisting electrode conductor 23 and the main electrode conductor 21, and a distance d2 is respectively between the assisting electrode conductor 22 and the main electrode conductor 21 and between the assisting electrode conductor 24 and the main electrode conductor 21. The distance d1 may be less or equal to the distance d2 based on restrictions of the disposition spaces.

The main electrode conductor 21, the assisting electrode conductor 22, the assisting electrode conductor 23, and the assisting electrode conductor 24 are all coupled to the controller 124. The main electrode conductor 21, the assisting electrode conductor 22, the assisting electrode conductor 23, and the assisting electrode conductor 24 are all, for example, electrode conductors composed of at least one metal material, and respectively capable of detecting the touch performed thereon by the user. For example, a capacitance value of the main electrode conductor 21 may be changed if the use touches the main electrode conductor 21. When the controller 124 detects that the change of the capacitance value of the main electrode conductor 21, the controller 124 may determine that the user is touching the main electrode conductor 21 or a position where the main electrode conductor 21 is located. The touch determination of the other assisting electrode conductors, i.e., the assisting electrode conductor 22, the assisting electrode conductor 23, and the assisting electrode conductor 24, are basically the same as the main electrode conductor 21 and thus, will not be repeated hereinafter.

It should be noticed that in the present embodiment, the main electrode conductor 21 is the core of the detecting module 122. That is, the controller 124 performs the follow-up determination operation only when the main electrode conductor 21 detects a touch. The assisting electrode conductor 22, the assisting electrode conductor 23, and the assisting electrode conductor 24 are disposed in the periphery of the main electrode conductor 21 so as to determine whether the user directly taps the main electrode conductor 21, or accidentally touches the main electrode conductor 21 during the process of performing a dragging, swiping, or parking operation.

Generally, if the user directly taps on the main electrode conductor 21, the user commonly may not touch the assisting electrode conductor 22, the assisting electrode conductor 23, and the assisting electrode conductor 24. Conversely, if accidentally touching the main electrode conductor 21 during the process of performing the dragging, swiping, or parking operation on the electronic device 10, the user must have a great probability simultaneously touching one of the assisting electrode conductor 22, the assisting electrode conductor 23 and the assisting electrode conductor 24 or a combination thereof, so that a capacitance value of one of the assisting electrode conductor 22, the assisting electrode conductor 23, and the assisting electrode conductor 24 or the combination thereof is changed simultaneously with the capacitance value of the main electrode conductor 21.

In the present embodiment, when the controller 124 determines that the touch is detected by the main electrode conductor 21, but not detected by the assisting electrode conductor 22, the assisting electrode conductor 23 and the assisting electrode conductor 24, the controller 124 may transmit a key signal to the processing system. In contrary, when the controller 124 determines that the touch is detected not only by the main electrode conductor 21, but also by the one of the assisting electrode conductor 22, the assisting electrode conductor 23 and the assisting electrode conductor 24 or the combination thereof, the controller does not transmit the key signal to the processing system so as to reduce the probability of the malfunction occurring in the electronic device 10.

Furthermore, in order to determine whether the touch is simultaneously detected by the main electrode conductor 21, the assisting electrode conductor 22, the assisting electrode conductor 23, and the assisting electrode conductor 24, the controller 124 may set a predetermined time (e.g., 0.1˜0.2 seconds). If the touch is detected by the main electrode conductor 21 and one of the assisting electrode conductor 22, the assisting electrode conductor 23, and the assisting electrode conductor 24 or the combination thereof within the predetermined time, the controller 124 may also determine that the touch is a malfunction of the user without generating the key signal due to the user touching the main electrode conductor 21.

In each of the following embodiments, the basic operations among the main electrode conductor, the assisting electrode conductors, and the controller that is described in detail in the first embodiment will remain, and only relative positions of shapes and disposition of the main electrode conductor and/or the assisting electrode conductors are adjusted.

### Second Embodiment

FIG. 3 is a schematic diagram of the detecting module 122 according to a second embodiment of the present invention. Referring to FIG. 3, the detecting module 122 includes a main electrode conductor 31, the assisting electrode conductor 22, the assisting electrode conductor 23, and the assisting electrode conductor 24. The assisting electrode conductor 22, the assisting electrode conductor 23, and the assisting electrode conductor 24 are disposed around the main electrode conductor 31. The description in connection with the disposition and operations of the main electrode conductor 31, the assisting electrode conductor 22, the assisting electrode conductor 23, and the assisting electrode conductor 24 may refer to the description in connection with the first embodiment, and thus, will not be repeated hereinafter.

The difference between the present embodiment and the first embodiment is that, in the present embodiment, an opening 32 is in the centre of the main electrode conductor 31. Thereby, when a light source device (e.g., light emitting diode (LED)) is disposed below the detecting module 122, and the metal material of the main electrode conductor 31 is non-transparent or low-transparent, the light source (e.g., the LED light source) below the detecting module 122 may pass through the opening 32.

In an embodiment, the assisting electrode conductor 22, the assisting electrode conductor 23, and the assisting electrode conductor 24 of FIG. 2 or FIG. 3 are not disposed simultaneously. Only one or two of the assisting electrode conductor 22, the assisting electrode conductor 23 and the assisting electrode conductor 24 may be disposed on the electronic device 10. For example, only the assisting electrode conductor 23 is disposed, but the assisting electrode conductor 22 and assisting electrode conductor 24 are not disposed. Alternatively, in another embodiment, the assisting electrode conductor 22, the assisting electrode conductor 23, and the assisting electrode conductor 24 are connected to form a single assisting electrode conductor.

### Third Embodiment

FIG. 4 is a schematic diagram of the detecting module 122 according to a third embodiment of the present invention. Referred to FIG. 4, in the present embodiment, the detecting module 122 includes a main electrode conductor 41, an assisting electrode conductor 42, and an assisting electrode conductor 43. The assisting electrode conductor 42 and the assisting electrode conductor 43 are disposed around the main electrode conductor 41.

In detail, if it is defined that the main electrode conductor 41 has a side 41_1, a side 41_2, a side 41_3, and a side 41_4, the assisting electrode conductor 42 is disposed around and adjacent to the side 41_1 and the side 41_2 of the main electrode conductor 41, and the assisting electrode conductor 43 is disposed around and adjacent to the side 41_3 and the side 41_4 of the main electrode conductor 41.

As shown in FIG. 4, the assisting electrode conductor 42 may include a basic part 42_1 and an extended part 42_2, the assisting electrode conductor 43 may includes a basic part 43_1 and an extended part 43_2, and the basic part 42_1 is opposite to the basic part 43_1. The basic part 42_1 is adjacent to the side 41_1 of the main electrode conductor 41, and the extended part 42_2 is adjacent to the side 41_2 of the main electrode conductor 41 and extended toward the basic part 43_1. The basic part 43_1 is adjacent to the side 41_3 of the main electrode conductor 41, and the extended part 43_2 is adjacent to side 41_4 of the main electrode conductor 41 and extended toward the basic part 42_1. In particular, the extended part 42_2 is not connected with the basic part 43_1, and the extended part 43_2 is also not connected with the basic part 42_1 so as to prevent touch-sensing capabilities of the assisting electrode conductor 42 and assisting electrode conductor 43 from being reduced.

In order to explicit clarify the directionality in FIG. 4, referring to FIG. 1 and FIG. 4, in the present embodiment, the extended part 42_2 of the assisting electrode conductor 42 may be substantially disposed between the display 11 and the main electrode conductor 41 to determine whether the user mistakenly touches the main electrode conductor 41 when operating the display 11. Moreover, it is assumed that a distance d1 is respectively between the extended part 42_2 and the main electrode conductor 41 and between the extended part 43_2 and the main electrode conductor 41, and a distance d2 is respectively between the basic part 42_1 and the main electrode conductor 41 and between the basic part 43_1 and the main electrode conductor 41. The distance d1 may be less or equal to the distance d2 based on restrictions of the disposition spaces.

### Fourth Embodiment

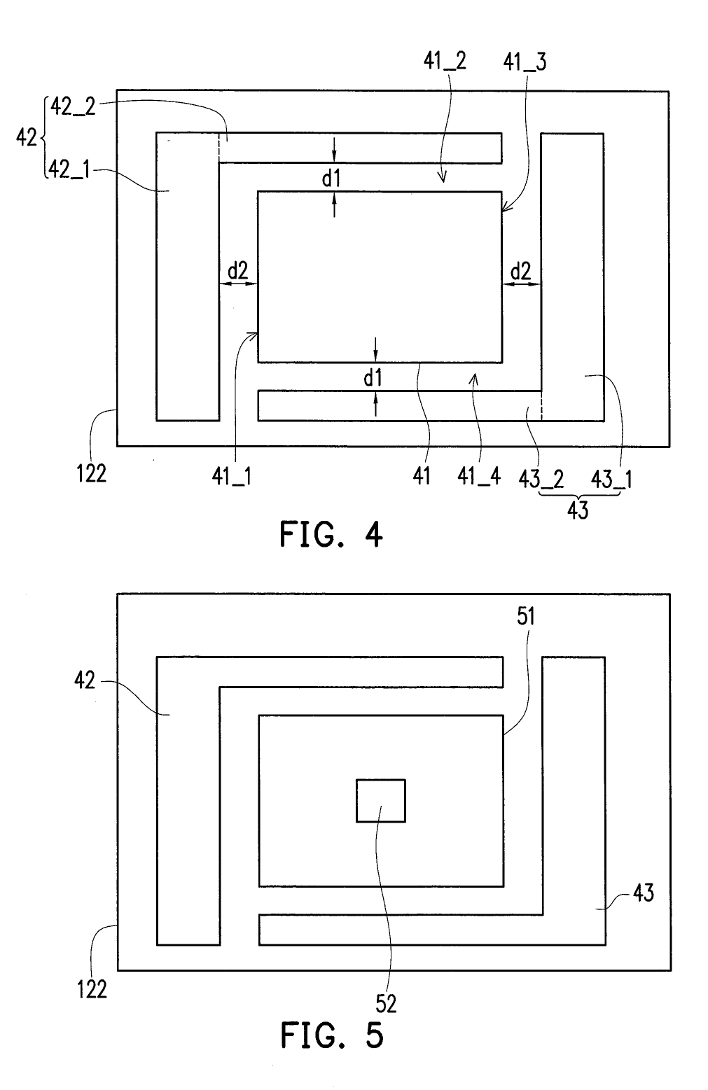

FIG. 5 is a schematic diagram of the detecting module 122 according to a fourth embodiment of the present invention. Referring to FIG. 5, the detecting module 122 includes a main electrode conductor 51, the assisting electrode conductor 42, and the assisting electrode conductor 43. The assisting electrode conductor 42 and the assisting electrode conductor 43 are disposed around the main electrode conductor 51. The disposition and operations of the main electrode conductor 51, the assisting electrode conductor 42, and the assisting electrode conductor 43 may refer to the description in connection with the third embodiment and thus, will not be repeated hereinafter.

The difference between the present embodiment and the third embodiment is that, in the present embodiment, the main electrode conductor 51 has an opening 52 (while the main electrode conductor 41 does not have an opening). Thereby, when a light source device (e.g., LED) is disposed below the detecting module 122, and the metal material of the main electrode conductor 51 is non-transparent or low-transparent, the light source (e.g., the LED light source) below the detecting module 122 may pass through the opening 52.

In an embodiment, the assisting electrode conductor 42 and the assisting electrode conductor 43 of FIG. 4 or FIG. 5 are not disposed simultaneously. Only the assisting electrode conductor 42 or the assisting electrode conductor 43 may be disposed on the electronic device 10. For example, only the assisting electrode conductor 42 is disposed, but the assisting electrode conductor 43 is not disposed. Alternatively, in another embodiment, the assisting electrode conductor 42 and the assisting electrode conductor 43 are connected to form a single assisting electrode conductor.

### Fifth Embodiment

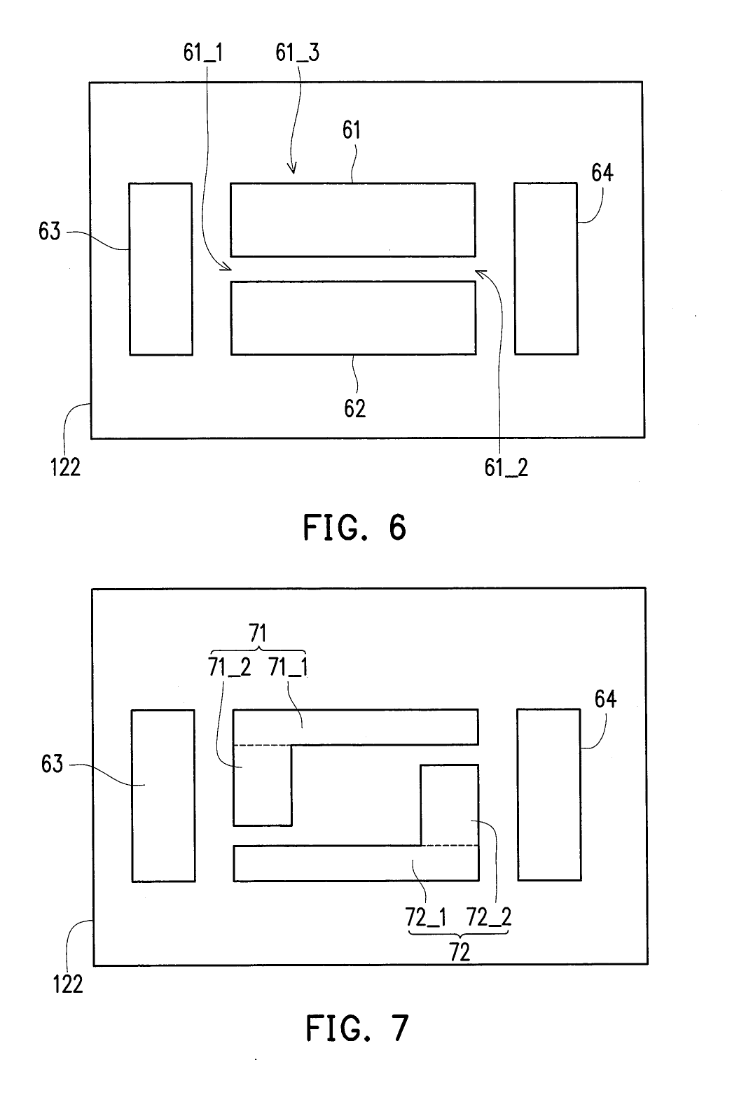

FIG. 6 is a schematic diagram of the detecting module 122 according to a fifth embodiment of the present invention. Referred to FIG. 6, in the present embodiment, the detecting module 122 includes a main electrode conductor 61, a main electrode conductor 62, an assisting electrode conductor 63, and an assisting electrode conductor 64. The assisting electrode conductor 63 and the assisting electrode conductor 64 are disposed around the main electrode conductor 61 and the main electrode conductor 62.

In detail, if it is defined that the main electrode conductor 61 and the main electrode conductor 62 have common sides 61_1 and 61_2, then the assisting electrode conductor 63 is disposed adjacent to the side 61_1, the assisting electrode conductor 64 is disposed adjacent to the side 61_2, and the assisting electrode conductor 63 is disposed opposite to the assisting electrode conductor 64. Moreover, the disposition manners of the assisting electrode conductor 63 and the assisting electrode conductor 64 may refer to those of the assisting electrode conductor 22 and the assisting electrode conductor 24 in the first embodiment.

In order to explicitly clarify the directionality in FIG. 6, referring to FIG. 1 and FIG. 6, in the present embodiment, the main electrode conductor 61 may be substantially disposed between the display 11 and the main electrode conductor 62 so as to determine whether the user mistakenly touches the main electrode conductor 61 and/or the main electrode conductor 62 when operating the display 11. For example, in FIG. 6, it is assumed that the main electrode conductor 61 further has a side 61_3, the display 11 is, for example, disposed adjacent to the side 61_3. In particular, the difference between the present embodiment and the aforementioned first embodiment through the fourth embodiment is that, in the present embodiment, the main electrode conductor 61 and the main electrode conductor 62 are simultaneously serves as the core of the detecting module 122. Therefore, when the controller 124 determines that a touch is simultaneously detected by the main electrode conductor 61 and the main electrode conductor 62 or within a predetermined time (e.g., 0.1˜0.2 seconds), but not detected by the assisting electrode conductor 63 and the assisting electrode conductor 64 within the predetermined time, the controller 124 may transmit a key signal to the processing system. Conversely, if the touch is detected by only the main electrode conductor 61, only the main electrode conductor 62, or respectively by the main electrode conductors 61 and 62 but an interval for being detected by the main electrode conductors 61 and 62 is over the predetermined time (e.g., 0.1˜0.2 seconds), or alternatively, the touch is not only simultaneously detected by the main electrode conductors 61 and 62 but also by one of the assisting electrode conductor 63 and the assisting electrode conductor 64 or a combination thereof, the controller 124 does not transmit the key signal to the processing system. As a result, the probability of the malfunction occurring in the electronic device 10 is reduced.

### Sixth Embodiment

FIG. 7 is a schematic diagram of the detecting module 122 according to a sixth embodiment of the present invention. Referring to FIG. 7, the detecting module 122 includes a main electrode conductor 71, a main electrode conductor 72, the assisting electrode conductor 63 and the assisting electrode conductor 64. The disposition of the main electrode conductor 71, the main electrode conductor 72, the assisting electrode conductor 63 and the assisting electrode conductor 64 may refer to the description in connection with the fifth embodiment, and thus, will not be repeated.

The difference between the present embodiment and the sixth embodiment is that in the present embodiment, the main electrode conductor 71 includes a basic part 71_1 and an extended part 71_2, the main electrode conductor 72 includes a basic part 72_1 and an extended part 72_2, and the basic part 71_1 is disposed opposite to the basic part 72_1. The extended part 71_2 is adjacent to the assisting electrode conductor 63 and extended toward the basic part 72_1, and the extended part 72_2 is adjacent to the assisting electrode conductor 64 and extended toward the basic part 71_1. In particular, the extended part 71_2 is not connected with the basic part 72_1, and the extended part 72_2 is also not connected with the basic part 71_1 so as to prevent touch-sensing capabilities of the main electrode conductors 71 and 72 from being reduced.

Accordingly, when a light source device (e.g., an LED) is disposed below the detecting module 122, and the metal material of the main electrode conductor 71 is non-transparent or low transparent, the light source (e.g., the LED light source) below the detecting module 122 may pass through an opening between the main electrode conductor 71 and the main electrode conductor 72.

In an embodiment, the assisting electrode conductor 63 and the assisting electrode conductor 64 of FIG. 6 or FIG. 7 are not disposed simultaneously. Only the assisting electrode conductor 63 or the assisting electrode conductor 64 may be disposed on the electronic device 10. For example, only the assisting electrode conductor 63 is disposed, but the assisting electrode conductor 64 is not disposed.

Furthermore, the present invention also provides a signal generating method of a key module, which is suitable for the key module 122 and/or the electronic device 10 described in the first embodiment through the sixth embodiment in the above.

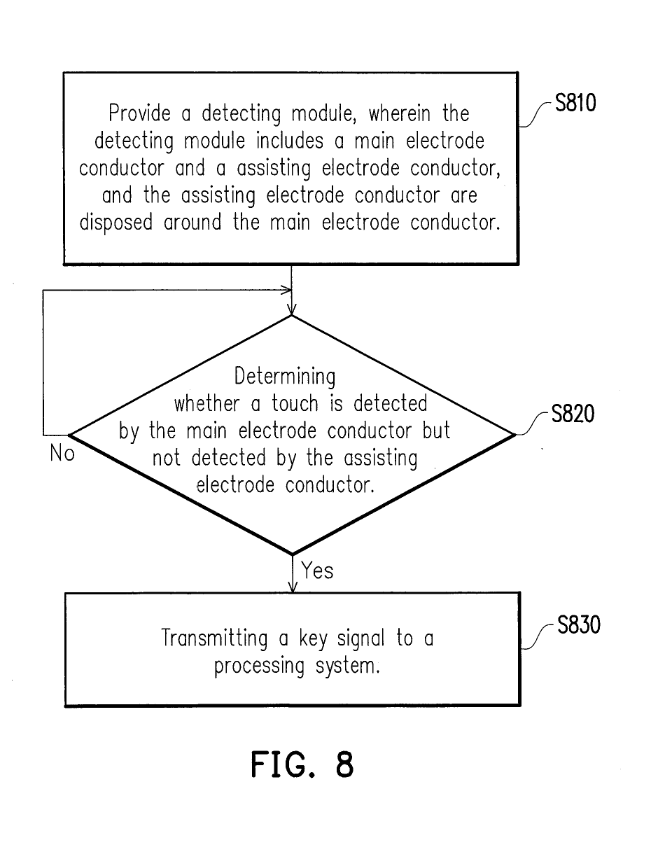

For example, FIG. 8 is a flowchart of a signal generating method of a key module according to an embodiment of the present invention. Referring to FIG. 8, in step S810, a detecting module is provided. The detecting module includes a main electrode conductor and at least one assisting electrode conductor, and the assisting electrode conductor is disposed around the main electrode conductor. In step S820, whether a touch is detected by the main electrode conductor, but not detected by the assisting electrode conductor is determined. Then, in step S830, when the touch is detected by the main electrode conductor, but not detected by the assisting electrode conductor, a key signal is transmitted to a processing system. Furthermore, after step S820, except for the case where the touch is detected by the main electrode conductor, but not detected by the assisting electrode conductor, step S820 is repeatedly performed, but the key signal is not transmitted to the processing system.

The implementation details regarding the signal generating method of the key module may sufficiently refer to and be taught from the descriptions in connection with the first embodiment through the sixth embodiment in the above, and thus, will not be repeated.

In light of the foregoing, the present invention provides the key module and the signal generating method thereof, where the key signal is generated only when the touch is detected by the main electrode conductor in the key module, but not detected by the assisting electrode conductor so as to effectively prevent the electronic device from malfunction due to accident touches by the user.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A key module, suitable for an electronic device having a processing system, the key module comprising:
a detecting module, comprising:
a main electrode conductor; and
at least one assisting electrode conductor, disposed around the main electrode conductor; and
a controller, coupled to the main electrode and the at least one assisting electrode conductor,
wherein when the controller determines that a touch is detected by the main electrode conductor touch but not detected by the at least one assisting electrode conductor, the controller transmits a key signal to the processing system.

2. The key module of claim 1, wherein the at least one assisting electrode conductor comprise a first assisting electrode conductor, a second assisting electrode conductor, and a third assisting electrode conductor, the first assisting electrode conductor is disposed adjacent to a first side of the main electrode conductor, the second assisting electrode conductor is disposed adjacent to a second side of the main electrode conductor, the third assisting electrode conductor is disposed adjacent to a third side of the main electrode conductor, and the first assisting electrode conductor is disposed opposite to the third assisting electrode conductor.

3. The key module of claim 2, wherein the electronic device further has a display, and the second assisting electrode conductor is further disposed between the display and the main electrode conductor.

4. The key module of claim 1, wherein the at least one assisting electrode conductor comprise a first assisting electrode conductor and a second assisting electrode conductor, the first assisting electrode conductor is disposed around and adjacent to a first side and a second side of the main electrode conductor, and the second assisting electrode conductor is disposed around and adjacent to a third side and a fourth side of the main electrode conductor.

5. The key module of claim 4, wherein the first assisting electrode conductor comprises a first basic part and a first extended part, the second assisting electrode conductor comprises a second basic part and a second extended part, and the first basic part is opposite to the second basic part,
wherein the first basic part is adjacent to the first side of the main electrode conductor, and the first extended part is adjacent to the second side of the main electrode conductor and extended toward the second basic part,
wherein the second basic part is adjacent to the third side of the main electrode conductor, and the second extended part is adjacent to the fourth side of the main electrode conductor and extended toward the first basic part.

6. The key module of claim 5, wherein the electronic device further has a display, and the first extended part is further disposed between the display and the main electrode conductor.

7. The key module of claim 1, wherein the main electrode conductor comprises a first main electrode conductor and a second main electrode conductor, the first main electrode conductor is disposed opposite to the second main electrode conductor, the assisting electrode conductor comprise a first assisting electrode conductor and a second assisting electrode conductor, the first assisting electrode conductor is disposed adjacent to the first main electrode conductor and a first side of the second main electrode conductor, and the second assisting electrode conductor is disposed adjacent to the first main electrode conductor and a second side of the second main electrode conductor.

8. The key module of claim 7, wherein the electronic device further has a display, and the first main electrode conductor is further disposed between the display and the second main electrode conductor.

9. The key module of claim 7, wherein the first main electrode conductor comprises a first basic part and a first extended part, the second main electrode conductor comprises a second basic part and a second extended part, and the first basic part is disposed opposite to the second basic part,
wherein the first extended part is adjacent to the first assisting electrode conductor and extended toward the second basic part, and the second extended part is adjacent to the second assisting electrode conductor and extended toward the first basic part.

10. A signal generating method of a key module, suitable for a electronic device having a processing system, the method comprising:
providing a detecting module of the key module, wherein the detecting module comprises a main electrode conductor and at least one assisting electrode conductor, and the at least one assisting electrode conductor is disposed around the main electrode conductor;
determining whether a touch is detected by the main electrode conductor touch but not detected by the at least one assisting electrode conductor; and
when the touch is detected by the main electrode conductor but not detected by the at least one assisting electrode conductor, transmitting a key signal to the processing system.

11. The method of claim 10, wherein the at least one assisting electrode conductor comprise a first assisting electrode conductor, a second assisting electrode conductor, and a third assisting electrode conductor, the first assisting electrode conductor is disposed adjacent to a first side of the main electrode conductor, the second assisting electrode conductor is disposed adjacent to a second side of the main electrode conductor, the third assisting electrode conductor is disposed adjacent to a third side of the main electrode conductor, and the first assisting electrode conductor is disposed opposite to the third assisting electrode conductor.

12. The method of claim 11, wherein the electronic device further has a display, and the second assisting electrode conductor is further disposed between the display and the main electrode conductor.

13. The method of claim 10, wherein the at least one assisting electrode conductors comprise a first assisting electrode conductor and a second assisting electrode conductor, the first assisting electrode conductor is disposed around and adjacent to a first side and a second side of the main electrode conductor, and the second assisting electrode conductor is disposed around and adjacent to a third side and a fourth side of the main electrode conductor.

14. The method of claim 13, wherein the first assisting electrode conductor comprises a first basic part and a first extended part, the second assisting electrode conductor comprises a second basic part and a second extended part, and the first basic part is opposite to the second basic part,
wherein the first basic part is adjacent to the first side of the main electrode conductor, and the first extended part is adjacent to second side of the main electrode conductor and extended toward the second basic part,
wherein the second basic part is adjacent to the third side of the main electrode conductor, and the second extended part is adjacent to the fourth side of the main electrode conductor and extended toward the first basic part.

15. The method of claim 14, wherein the electronic device further has a display, and the first extended part is further disposed between the display and the main electrode conductor.

16. The method of claim 10, wherein the main electrode conductor comprises a first main electrode conductor and a second main electrode conductor, the first main electrode conductor is disposed opposite to the second main electrode conductor, the at least one assisting electrode conductor comprise a first assisting electrode conductor and a second assisting electrode conductor, the first assisting electrode conductor is disposed adjacent to the first main electrode conductor and a first side of the main electrode conductor, and the second assisting electrode conductor is disposed adjacent to the first main electrode conductor and a second side of the main electrode conductor.

17. The method of claim 16, wherein the electronic device further has a display, and the first main electrode conductor is further disposed between the display and the second main electrode conductor.

18. The method of claim 16, wherein the first main electrode conductor comprises a first basic part and a first extended part, the second main electrode conductor comprises a second basic part and a second extended part, and the first basic part is disposed opposite to the second basic part,
wherein the first extended part is adjacent to the first assisting electrode conductor and extended toward the second basic part, and the second extended part is adjacent to the second assisting electrode conductor and extended toward the first basic part.
